(19) United States
(12) Patent Application Publication
(10) Pub. No.: US 2010/0091463 A1
(43) Pub. Date: Apr. 15, 2010

(54) COOLING BODY

(76) Inventors: Isabell Buresch, Illertissen (DE); Karine Brand, Ulm (DE)

Correspondence Address: FLYNN THIEL BOUTELL & TANIS, P.C., 2026 RAMBLING ROAD, KALAMAZOO, MI, 49008-1631, US

(21) Appl. No.: 12/450,030

(22) PCT Filed: Apr. 23, 2008
(86) PCT No.: PCT/EP2008/003241

§ 371 Date: Sep. 8, 2009

(30) Foreign Application Priority Data
Apr. 27, 2007 (DE) 10 2007 019 885.1

(51) Int. Cl. H05K 7/20; H01L 23/367

(52) U.S. Cl. 361/718; 257/E23.102; 361/711

(57) ABSTRACT

The invention relates to a cooling body for power electronic modules or for semiconductor elements having a flat metal heat dissipation plate, wherein the heat dissipation plate on the side facing the power electronic module or the semiconductor element comprises a surface structured in the manner of a matrix and having protruding elevations, wherein the heat dissipation plate and surface structured in the manner of a matrix are made out of one piece.

The invention relates to a cooling body for power electronic modules or for semiconductor components in accordance with the preamble of claim 1.

Transistors and microprocessors generate a considerable amount of waste heat during operation. In order to prevent overheating that may lead to malfunctions or to the destruction of the components, in the case of modern processors for personal computers, IGBTs, MOSFETs, inter alia, the natural emission of heat is inadequate without further aids. In order to ensure optimum cooling and little power loss, the waste heat has to be conducted away from the component as rapidly as possible and the heat dissipating surface has to be enlarged. For cooling purposes, often a cooling body is additionally arranged on the heat dissipating plate by means of thermally conductive paste. The cooling can be effected in a manner assisted by means of air or liquid. In the first case, the cooling body is a ribbed metal block, often composed of aluminum or copper, often with fans additionally fitted on the cooling body. In the second case, the cooling body comprises a heat exchanger through which fluid flows.

Power electronic modules such as, for example, IGBTs, DCB elements, MOSFETs, inter alia, are nowadays constructed in multiple parts. A significant problem in production and in subsequent operation is the great difference between the coefficients of thermal expansion of the ceramic carrier and of the Cu heat dissipating plates that serve as a mechanical stabilizer and for heat dissipation. During the soldering/bonding process (DCB), by way of example, solder composed of an SnAgCu alloy is heated beyond the melting point at 221° C. up to a soldering temperature of 250-260° C. and the heat dissipating plate is heated to up to 260° C. In the course of subsequent cooling, the complete component deforms since the coefficients of thermal expansion of the ceramic with 4-6×10⁻⁶ 1/K differ very greatly from the value of the Cu heat dissipating plate with 17×10⁻⁶ 1/K. Under unfavorable conditions, the stresses that occur can become so great that the ceramic cracks. This could be remedied by a heat dissipating plate composed of a material having a lower coefficient of expansion and a sufficiently good thermal conductivity. However, these materials are very expensive owing to their composition and their production processes.

With the introduction of SMD technology, the possibility alternatively also arose of mounting chip carriers with their connections by means of connection wires directly onto conventional epoxide-glass laminates. In the case of a leadless ceramic chip carrier (LCCC), however, high shear stresses between chip carrier and soldered joint likewise occur as a result of the coefficient of linear expansion of approximately 6-8×10⁻⁶ 1/K relative to the higher value of approximately 12-15×10⁻⁶ 1/K of the employed material of the printed circuit board. Said stresses can lead to the chip carriers being torn away from the soldered joint or even to cracks in the chip carrier.

This can be remedied by the incorporation of core substrates in multilayer circuits, Cu-Invar-Cu then principally being used. The Cu-Invar-Cu layers are arranged symmetrically in the multilayer and can be used as ground and supply planes. This arrangement affords the advantage that a coefficient of thermal expansion in the range of 1.7-2×10⁻⁶ l/K, which is adapted to the value of the ceramic chip carrier, is present near the surface of the circuit. The larger the SMD component, the more it is necessary to adapt the coefficient of expansion of the multilayer surface to that of ceramic.

In alternative solutions, in the Cu-Invar-Cu multi-layer, the Invar can also be arranged as a thick metal core of 0.5 mm to 1.5 mm into the center of the multilayer. Besides limiting the coefficient of expansion at the surface of the circuit, the advantage resides primarily in the additional good heat dissipation. As a result of this, mounting of SMD components on both sides is also possible. Besides the control of expansion of the surface, the Cu-Invar-Cu printed circuit boards can additionally perform the function of a heat sink.

As a further specific solution, the document WO 2006/109660 A1 discloses a cooling body for power semiconductor components. An interlayer for reducing thermal stresses is arranged at the common area of contact between the cooling body and the semiconductor component. Said interlayer comprises an aluminum plate having a multiplicity of holes for reducing stress. On the component side, the interlayer is soldered to the cooling body and to a metallic surface layer applied over the whole area on an insulator substrate.

Furthermore, the document DE 101 34 187 B4 discloses a cooling device for power semiconductor modules, comprising a housing, connection elements, a ceramic substrate and semiconductor components. The heat dissipation from a power semiconductor module is effected by means of individual cooling elements, which, for their part, comprise a planar base body and a finger-like extension. These individual cooling elements are arranged in matrix-like fashion in rows and columns at the surface to be cooled. Those surfaces of the individual cooling elements which do not face the component or module to be cooled can have surfaces which are smooth or structured in any desired fashion for better heat dissipation.

The invention is based on the object of further developing a cooling body for power electronic modules, the assemblage of which withstands the thermally dictated stresses.

The invention is expressed by the features of claim 1. The further claims that refer back relate to advantageous embodiments and developments of the invention.

The invention includes a cooling body for power electronic modules or for semiconductor components having a planar metallic heat dissipating plate wherein the heat dissipating plate, on the side facing the power electronic module or the side facing the semiconductor component, has a surface structured in matrix-type fashion and having protruding elevations, wherein the heat dissipating plate and surface structured in matrix-type fashion are produced from one piece.

In this case, the invention is based on the consideration that the cooling body surface structured in matrix-type fashion is suitable for absorbing the thermally dictated stresses that occur by means of elastic deformation. The metallic heat dissipating plate having the structured surface can be composed of highly conductive copper or a copper alloy. Examples that may be mentioned in this context include E-Cu, SE-Cu, ETP-Cu, OFE-Cu, CuFe0.1, CuSn0.15 in the soft state. In this case, the structured surface can be produced integrally from a strip material with the aid of a single- or multistage rolling or embossing process. The forming process usually gives rise to consolidation of the material in the structured contours. Material consolidation takes place in particular in the region of the webs formed between the individual elevations. The structure obtained can then additionally be softened with the aid of a laser or by heat treatment in a furnace in order to bring the webs of the contour to a softest possible state, which webs can absorb the changes in length as a result of thermal expansion. Milling, extrusion or etching may also be suitable as alternative structuring methods.

The cooling body is soldered with its structured surface for example under the ceramic substrate. The webs or contours can thus absorb the stresses that occur without deformations of a module occurring. The particular advantage is that the assemblage produced by the cooling body and the power electronic module or the semiconductor component withstands the thermally dictated stresses within the scope of elastic deformations of the individual materials. In this case, it is also possible to use materials having very different coefficients of thermal expansion, without the thermally dictated stresses leading to the separation of the material assemblage. The material assemblage can also withstand the stress states resulting from higher soldering temperatures.

In one preferred configuration of the invention, the structured surface of the cooling body can have truncated-pyramid-like or truncated-cone-like elevations. This comparatively simple structure has a particularly small common area of contact between the elevations and the power electronic module or semiconductor component. The elevations thickening toward the heat dissipating plate make a contribution to the heat spreading, that is to say the areal distribution of the heat input into the cooling body.

In a further advantageous configuration of the invention, the structured surface can have mushroom-shaped elevations. In this case, the heat dissipating plate is structured in the x and y directions, such that T-shaped mushroom structures or else pyramidal structures with webs as connection toward the metallic heat dissipation plate correspondingly absorb the expansion. For this purpose, the contour surfaces are finally upset by rolling or embossing. The structure narrows particularly in the central region of the elevations, whereby elastically deformable regions are formed there, these regions being particularly advantageously suitable for reducing stresses in the material.

The structured surface can advantageously have peg-like or needle-like elevations. Alternatively, rib-like or crossrib-like elevations can also be formed. Depending on the requirement, the individual structures can also be present in combination with one another. For example in the case of a local heat input of a heat source from the module to the cooling body, locally different structures can be used in directly adjacent fashion, which structures are particularly advantageously suitable for heat dissipation or heat spreading.

In an advantageous configuration, the structure size of the structured surface can be less than one millimeter, in principle, but preferably between 0.5 and 20 mm. The width B, length L and diameter D and height H of such microstructures can have dimensions of from a few micrometers up to a number of millimeters. The height H of the structure can be variable. The ratio of the height H of an elevation to the lateral extent B, L, D of an elevation can advantageously be at least 1:1. With geometrical ratios below this quotient, there is the risk that stresses in the material can no longer be compensated for elastically and the assemblage can thereby crack.

In a particularly preferred configuration of the invention, the interspace between the elevations can be filled with a low-expansion iron-nickel alloy having the composition on the basis of Fe: 64% and Ni: 36%. In this case, the metallic heat dissipating plate can be composed of copper or a copper alloy. The combination of copper and the iron-nickel alloy affords the advantage that two materials having a differing thermal expansion are present at the microstructured surface. The iron-nickel alloy has a coefficient of thermal expansion of 1.7 to 2.0×10⁻⁶ 1/K, which corresponds approximately to the value of the ceramic chip carrier materials. As a result of filling the interspace formed by the elevations, it is possible to produce a simple areal soldering connection of the cooling body and a power electronic module, for example.

Advantageously, the heat dissipating plate, on the side facing away from the power electronic module or the side facing away from the semiconductor component, additionally can have in matrix-like fashion a multiplicity of structured elevations, for example in the form of ribs or pegs of the order of magnitude of 0.5 to 20 mm, for heat dissipation. For this purpose, the heat dissipating plate can be structured on both sides, such that the otherwise required ribbed cooling body and the thermally conductive paste for air cooling can additionally be obviated, thereby eliminating the thermal resistance caused by previous solutions with thermally conductive paste. The structured elevations and the heat dissipating plate can accordingly be formed integrally. The production methods used include the same process technologies such as rolling, milling, extrusion, embossing or other methods in addition. One-part structures furthermore afford a cost advantage over solutions involving multiple parts.

Since this structure preferably serves for heat dissipation with air, it is important that a high area increase is thereby effected. Customary geometries are lamellae or so-called pins which can have a height of a number of centimeters and a spacing of greater than one millimeter. These lamellae or pins can also be mechanically fixed to the heat dissipating plate.

As an alternative, a cooling unit with closed fluid circuit can be arranged on that side of the heat dissipating plate which faces away from the power electronic module or that side of said heat dissipating plate which faces away from the semiconductor component. In this case, the structuring of the heat dissipating plate can be on both sides, such that the structured rear side functions directly as open flow channels/structures for the liquid cooling body. An additional cover composed of metal or plastic then closes off the heat exchanger.

Since this structure preferably serves for heat dissipation with the aid of a separate cooling medium, usually a glycol-water mixture or some other refrigerant that is conventional in the electronics industry, channels, channel sections or else pins should be formed as structures. The cooling can be ensured by a one-phase process, for example liquid cooling, or a two-phase process, for example evaporation. Customary structure heights are 0.5 mm to 10 mm, where the shaped channels can have widths of 20 μm to 3 mm.

Further exemplary embodiments of the invention are explained in greater detail with reference to schematic drawings.

In said drawings:

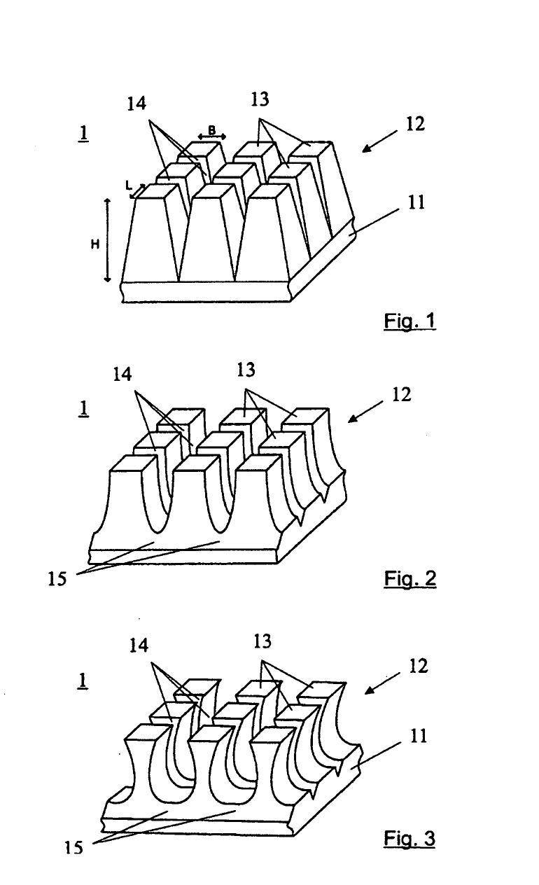

FIG. 1 shows a view of the structured surface of a cooling body with a planar underside,

FIG. 2 shows a further view of a configuration of the structured surface of a cooling body with a planar underside,

FIG. 3 shows a further view of a configuration of the structured surface of a cooling body with a planar underside,

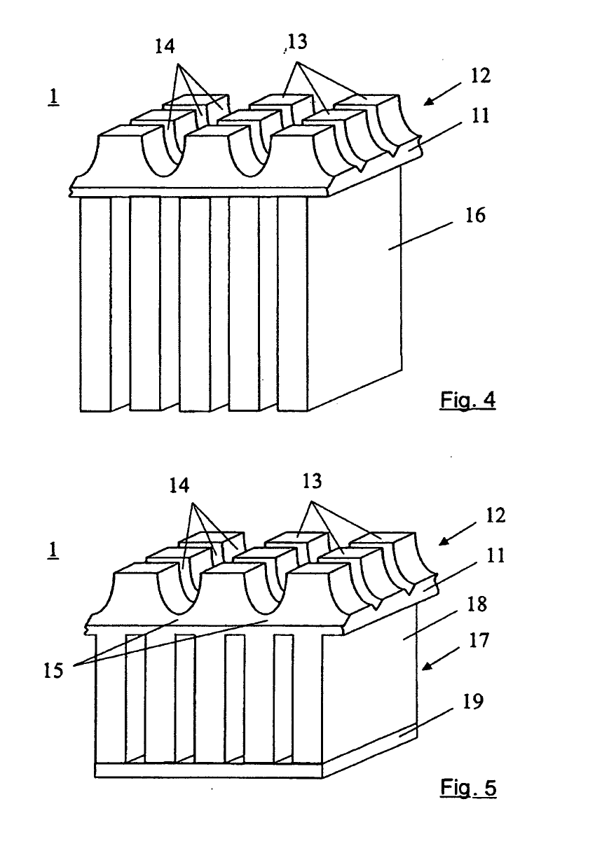

FIG. 4 shows a view of the structured surface of a cooling body with cooling elements arranged on the underside, and

FIG. 5 shows a view of the structured surface of a cooling body with a cooling unit with a closed fluid circuit arranged on the underside.

Mutually corresponding parts are provided with the same reference symbols in all the figures.

FIG. 1 shows a schematic view of the structured surface 12 of a cooling body 1 for power electronic modules or semiconductor components (not illustrated in the figure).

In terms of its basic form, the cooling body 1 comprises a planar metallic heat dissipating plate 11, the top side, that is to say the side facing a power electronic module or a semiconductor component, of said heat dissipating plate having a surface 12 structured in matrix-type fashion in the form of protruding elevations 13. In this case, the heat dissipating plate 11 and elevations 13 of the surface 12 structured in matrix-type fashion are produced from one piece. The underside of the heat dissipating plate 11, that is to say the side facing away from a power electronic module or a semiconductor component, is planar in this case. The elevations 13 are formed as truncated pyramids. The inter-space 14 between the elevations 13 is not filled.

The width B, length L and height H of such structures can have dimensions of from a few micrometers up to a number of millimeters. The ratio of the height H of an elevation 13 to the lateral extent B and L, respectively, of an elevation 13 is approximately 3:1 in this case. The height H of an elevation 13 generally tends to be greater than the lateral extent B and L, respectively, of said elevation.

FIG. 2 shows a further view of a configuration of the structured surface 12 of a cooling body 1 with a planar underside. The surface 12 structured in matrix-type fashion is embodied in the form of protruding truncated-pyramid-like elevations 13. The heat dissipating plate 11 and the elevations 13 of the surface 12 structured in matrix-type fashion are once again produced from one piece in this case.

The elevations 13 are formed as truncated pyramids, the base of which is thickened by webs 15 in the transition region toward the heat dissipating plate 11. This base form serves for further improving the contact area between substrate and heat dissipating plate 11. Once again, the interspace 14 between the elevations 13 is not filled with material.

FIG. 3 shows a further view of a configuration of the structured surface 12 of a cooling body 1 with a planar underside. In this case, the heat dissipating plate 11 is structured in the x and y directions such that the elevations 13 in the form of T-shaped mushroom structures in conjunction with pyramidal structures with webs 15 as connection toward the metallic heat dissipating plate 11 provides buffering in accordance with the different expansion. The structure narrows particularly in the neck region, that is to say in the central region of the elevations, whereby elastically deformable regions are formed there, these regions being particularly advantageously suitable for absorbing stresses as a result of thermal loading of the power electronic module.

FIG. 4 shows a view of the structured surface 12 of a cooling body 1 with cooling elements 16 arranged on the underside. In this case, a multiplicity of additional rib-like cooling elements 16 for heat dissipation are arranged on the underside of the heat dissipating plate 11. The cooling elements 16 are for example soldered or bonded mechanically or by means of thermally conductive paste to the heat dissipating plate 11 and therefore in two-piece form in this case.

However, the cooling elements 16 and the heat dissipating plate 11 can also be formed integrally. For this purpose, the heat dissipating plate is then structured on both sides, such that an additional cooling unit fixed by means of a thermally conductive paste for air cooling can be obviated, thereby eliminating the thermal resistance caused by previous solutions with thermally conductive paste. The production methods used include process technologies such as rolling, milling, extrusion, embossing or other methods in addition.

FIG. 5 shows a view of the structured surface 12 of a cooling body 1 with a cooling unit 17 with a closed fluid circuit arranged on the underside. Since this structure preferably serves for heat dissipation with the aid of a separate cooling medium, the structures formed are channels, having structure heights of 0.5 mm to 10 mm, where the shaped channels have widths of 20 μm to 3 mm.

For this purpose, a multiplicity of additional cooling ribs 18 for heat dissipation are arranged in matrix-like fashion on the underside of the heat dissipating plate 11, said cooling ribs being connected in one piece with the heat dissipating plate 11. An additional cover 18 composed of metal or plastic then closes up the heat exchanger.

In this case, the structuring of the heat dissipating plate 11 is on both sides and the entire structure apart from the cover 19 of the cooling unit 17 is integral, such that the structured rear side functions directly as open flow channels/structures for the liquid cooling body. Thus, the assemblage formed by the cooling body 1 and the power electronic module or the semiconductor component is produced such that it withstands the thermally dictated stresses within the scope of elastic deformations of the individual materials.

### LIST OF REFERENCE SYMBOLS

1 Cooling body
11 Heat dissipating plate
12 Structured surface
13 Elevations
14 Interspace
15 Webs
16 Structured elevations, cooling elements
17 Cooling unit
18 Cooling ribs
19 Cover
H Height of an elevation
B Width of a rectangular elevation
L Length of a rectangular elevation
D Diameter of a round elevation

1. A cooling body (1) for power electronic modules or for semiconductor components having a planar metallic heat dissipating plate (11), characterized in that the heat dissipating plate (11), on the side facing the power electronic module or the side facing the semiconductor component, has a surface (12) structured in matrix-type fashion and having protruding elevations (13), wherein the heat dissipating plate (11) and surface (12) structured in matrix-type fashion are produced from one piece.

2. The cooling body as claimed in claim 1, characterized in that the structured surface (12) has truncated-pyramid-like or truncated-cone-like elevations (13).

3. The cooling body as claimed in claim 1, characterized in that the structured surface (12) has mushroom-shaped elevations (13).

4. The cooling body as claimed in claim 1, characterized in that the structured surface (12) has peg-like or needle-like elevations (13).

5. The cooling body as claimed in claim 1, characterized in that the structured surface (12) has rib-like or crossrib-like elevations (13).

6. The cooling body as claimed in claim 1, characterized in that the structure size of the structured surface (12) is between 0.5 and 20 mm.

7. The cooling body as claimed in claim 1, characterized in that the ratio of the height (H) of an elevation (13) to the lateral extent (B, L, D) of an elevation (13) is at least 1:1.

8. The cooling body as claimed in claim 1, characterized in that the interspace (14) between the elevations (13) is filled with a low-expansion iron-nickel alloy.

9. The cooling body as claimed in claim 1, characterized in that the metallic heat dissipating plate (11) is composed of copper or a copper alloy.

10. The cooling body as claimed in claim 1, characterized in that the heat dissipating plate (11), on the side facing away from the power electronic module or the side facing away from the semiconductor component, additionally has in matrix-like fashion a multiplicity of structured elevations (16) for heat dissipation.

11. The cooling body as claimed in claim 10, characterized in that the structured elevations (16) and the heat dissipating plate (11) are formed integrally with the surface (12) structured in matrix-type fashion.

12. The cooling body as claimed in claim 1, characterized in that a cooling unit (17) with closed fluid circuit is arranged on that side of the heat dissipating plate (11) which faces away from the power electronic module or that side of said heat dissipating plate (11) which faces away from the semiconductor component.
